(19) United States
(12) Patent Application Publication
(10) Pub. No.: US 2023/0307893 A1
(43) Pub. Date: Sep. 28, 2023

(54) LIGHT EMITTING ELEMENT, LIGHT EMITTING ELEMENT ARRAY, LIGHT EMITTING COMPONENT, OPTICAL DEVICE, AND OPTICAL MEASUREMENT APPARATUS

(71) Applicant: FUJIFILM Business Innovation Corp., Tokyo (JP)

(72) Inventors: Takashi KONDO, Kanagawa (JP); Junichiro HAYAKAWA, Kanagawa (JP); Tomoaki SAKITA, Kanagawa (JP); Takafumi HIGUCHI, Kanagawa (JP); Kei TAKEYAMA, Kanagawa (JP)

(73) Assignee: FUJIFILM Business Innovation Corp., Tokyo (JP)

(21) Appl. No.: 17/938,920

(22) Filed: Sep. 6, 2022

(30) Foreign Application Priority Data
Mar. 28, 2022 (JP) 2022-052354

(51) Int. Cl. H01S 5/42; G01S 7/481

(52) U.S. Cl. CPC H01S 5/423; G01S 7/4815

(57) ABSTRACT

A light emitting element includes: a light emitting unit that has multiple semiconductor layers laminated, the light emitting unit having a length from a center of the light emitting unit to an end portion in a first direction shorter than a length from the center to an end portion in a second direction intersecting the first direction, in plan view; and a connection part that extends from the light emitting unit in the first direction and connects the light emitting unit to another semiconductor layer.

### CROSS-REFERENCE TO RELATED APPLICATIONS

This application is based on and claims priority under 35 USC 119 from Japanese Patent Application No. 2022-052354 filed Mar. 28, 2022.

### BACKGROUND

### (i) Technical Field

The present disclosure relates to a light emitting element, a light emitting element array, a light emitting component, an optical device, and an optical measurement apparatus.

### (ii) Related Art

JP2019-010749A discloses a laminate having an outermost layer/polyamide film/sealant layer structure, in which adhesive strength and pinhole generation during distribution/transportation are improved, and a method of producing the same.

Further, JP2000-294872A discloses an oxidized surface-emitting laser and a surface-emitting laser array, which have a simple fabrication process, are resistant to stress, and are highly reliable.

### SUMMARY

In the related art, a structure is known in which a plurality of semiconductor layers are laminated and a part of the post shape of a light emitting element configured like a post shape is connected to another semiconductor layer.

Here, in a case where the light emitting element is provided with a connection part with another semiconductor layer, oxygen is supplied not only to the center side of the semiconductor layer but also to the connection part side in a case where the semiconductor layer is oxidized. Thereby, there is a difference in the oxidized region between a part where the connection part is provided and a part where the connection part is not provided, and a shape of an unoxidized region of the semiconductor layer is distorted. Thus, there is room for improvement.

Aspects of non-limiting embodiments of the present disclosure relate to a light emitting element that is configured as follows. In a case where the light emitting element is provided with the connection part with another semiconductor layer, a ratio of a length in a direction along the connection part of the unoxidized region of the semiconductor layer to a length in a direction intersecting the direction along the connection part is made closer to 1:1.

Aspects of certain non-limiting embodiments of the present disclosure overcome the above disadvantages and/or other disadvantages not described above. However, aspects of the non-limiting embodiments are not required to overcome the disadvantages described above, and aspects of the non-limiting embodiments of the present disclosure may not overcome any of the disadvantages described above.

According to an aspect of the present disclosure, there is provided a light emitting element including: a light emitting unit that has a plurality of semiconductor layers laminated, the light emitting unit having a length from a center of the light emitting unit to an end portion in a first direction shorter than a length from the center to an end portion in a second direction intersecting the first direction, in plan view; and a connection part that extends from the light emitting unit in the first direction and connects the light emitting unit to another semiconductor layer.

### BRIEF DESCRIPTION OF THE DRAWINGS

Exemplary embodiment(s) of the present invention will be described in detail based on the following figures, wherein:

FIG. 1 is an equivalent circuit diagram of a light emitting component;

FIG. 2 is a diagram showing an example of a planar layout of the light emitting component;

FIG. 3 is a cross-sectional view taken along the line A-A of FIG. 2;

FIG. 4 is a diagram showing an example of a planar layout of LD/S12;

FIG. 5 is a first explanatory view showing a planar layout of a part of a light emitter;

FIG. 6 is a second explanatory view showing a planar layout of a part of a light emitter;

FIG. 7 is a third explanatory view showing a planar layout of a part of a light emitter;

FIG. 8 is a schematic diagram showing a configuration of an optical device;

FIG. 9 is a schematic diagram showing a configuration of an optical measurement apparatus comprising an optical device; and

FIG. 10 is a diagram showing a state where light is emitted from an optical measurement apparatus.

### DETAILED DESCRIPTION

Hereinafter, referring to the accompanying drawings, the present exemplary embodiment will be described.

### First Exemplary Embodiment

First, the first exemplary embodiment will be described.

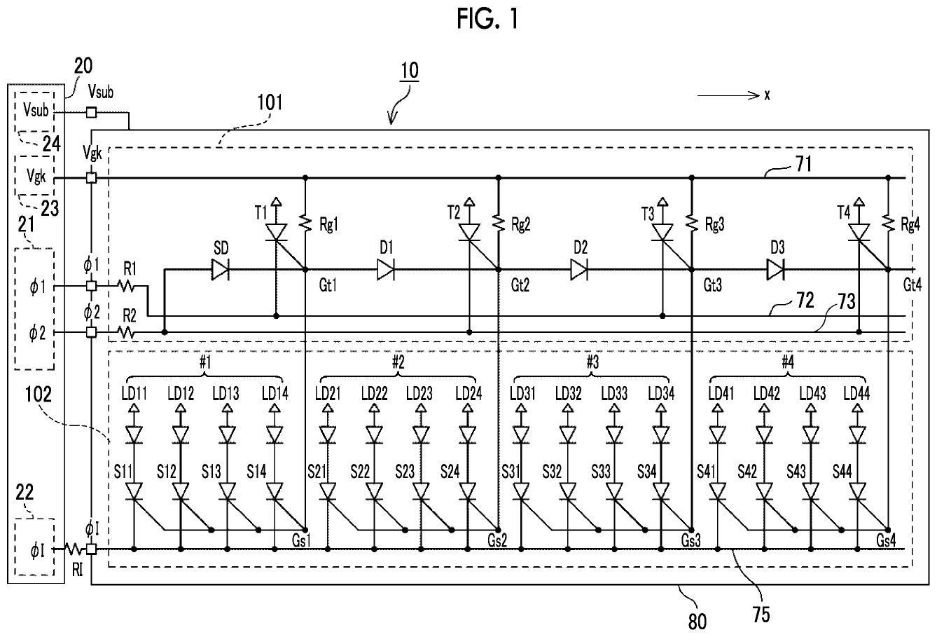

FIG. 1 is an equivalent circuit diagram of a light emitting component 10. Here, a control unit 20 that controls the light emitting component 10 is also shown. In FIG. 1, a left-right direction is the x direction.

The light emitting component 10 comprises a plurality of laser diodes LDs that emit laser light. The light emitting component 10 is configured as a self-scanning light emitting element array (SLED: Self-Scanning Light Emitting Device) to be described below. The laser diode LD is, for example, a vertical cavity surface emitting laser (VCSEL). Hereinafter, the light emitting element will be described as a laser diode LD. However, other light emitting devices such as a light emitting diode LED may be used.

The light emitting component 10 comprises a plurality of laser diode LD groups, each of which comprises a plurality of laser diodes LD. In FIG. 1, it is assumed that each laser diode LD group comprises four laser diodes LD as an example. In the following, the laser diode LD group will be referred to as laser diode LD group #1, #2, #3, . . . . In a case where each laser diode LD group is not distinguished, the laser diode LD group is referred to as a laser diode LD group or a laser diode LD group i (i is an integer of 1 or more). Although FIG. 1 shows four laser diode LD groups, the number of laser diode LD groups may be other than four.

The light emitting component 10 comprises a setting thyristor S for each laser diode LD. The laser diode LD and a setting thyristor S are connected in series.

Here, laser diodes LD belonging to the laser diode LD group #1 are referred to as laser diodes LD11 to 14. Here, in a case where the laser diode LDij (j is an integer of 1 or more) is represented, “i” is the number of the laser diode LD group, and “j” is the number of the laser diode LD in the laser diode LD group. The same reference numerals are given to the setting thyristors S. That is, the setting thyristor S included in the laser diode LD11 is referred to as a setting thyristor S11. In the example shown in FIG. 1, j is a number of 1 to 4. In FIG. 1, each laser diode LD group comprises the same number of laser diodes LD, but the number of laser diodes LD may differ between the laser diode LD groups. Further, the number of laser diodes LD in each laser diode LD group may be 2 or more.

In the present specification, the term “to” indicates a plurality of constituent elements, each of which is distinguished by a number, and means that the constituent elements described before and after “to” and the constituent elements having numbers therebetween are included. For example, the laser diodes LD11 to 14 include the laser diode LD11, the laser diode LD12, the laser diode LD13, and the laser diode LD14 in numerical order.

The light emitting component 10 further comprises a plurality of transfer thyristors T, a plurality of coupling diodes D, a plurality of power line resistors Rg, a start diode SD, and current-limiting resistors R1 and R2. Here, in a case of distinguishing a plurality of transfer thyristors T, the transfer thyristors T are numbered and distinguished, such as transfer thyristors T1, T2, T3, . . . . The same applies to the coupling diodes D and the power line resistors Rg. As will be described later, the transfer thyristor T1 is provided to correspond to the laser diode LD group #1. Therefore, in a case where the transfer thyristor T is represented as the transfer thyristor Ti, i corresponds to the same laser diode LD group. Accordingly, the transfer thyristor T may be referred to as a transfer thyristor T1. The same applies to the coupling diodes D and the power line resistors Rg. The transfer thyristor T is an example of the “setting unit”.

The number of transfer thyristors T in the light emitting component 10 may be a predetermined number. For example, the number may be 128, 512, or 1024. FIG. 1 shows a part corresponding to the transfer thyristors T1 to T4. The number of transfer thyristors T may be the same as the number of laser diode LD groups, may be greater than the number of laser diode LD groups, or may be small.

The transfer thyristors T are arranged in the x direction in order of transfer thyristors T1, T2, T3, . . . . The coupling diodes D are arranged in the x direction in order of the coupling diodes D1, D2, D3, . . . . The coupling diode D1 is provided between the transfer thyristor T1 and the transfer thyristor T2. The same applies to the other coupling diodes D. Further, the power line resistors Rg are also arranged in the x direction in order of the power line resistors Rg1, Rg2, Rg3, . . . .

The laser diode LD and the coupling diode D are two-terminal elements each comprising an anode and a cathode. The setting thyristor S and the transfer thyristor T are three-terminal elements each comprising an anode, a cathode, and a gate. The gate of the transfer thyristor T is referred to as a gate Gt, and the gate of the setting thyristor S is referred to as a gate Gs. In addition, in a case of distinguishing each gate, i is added in the same manner as described above.

Here, a part composed of the laser diodes LD and the setting thyristors S is set as a light emitter 102, and a part composed of the transfer thyristors T, the coupling diodes D, the start diode SD, the power line resistors Rg, and the current-limiting resistors R1 and R2 is set as a transfer unit 101.

Next, the connection relationship of each element (laser diode LD, setting thyristor S, transfer thyristor T, and the like) will be described.

As described above, the laser diodes LDij and the setting thyristors Sij are connected in series. That is, in the laser diode LD, the anode is connected to a reference potential Vsub (ground potential (GND) or the like), and the cathode is connected to the anode of the setting thyristor Sij.

Here, in the light emitting component 10, the setting thyristors S are laminated on the laser diodes LD. Hereinafter, the semiconductor layer laminate of the laser diode LD and the setting thyristor S will be referred to as “LD/S”. Further, the laser diode LD, which belongs to each laser diode LD group, and the setting thyristor S, which is provided for each laser diode LD, are collectively referred to as an “LD/S group”. The LD/S is an example of the “light emitting element”, and the LD/S group is an example of the “light emitting element group”.

The cathode of the setting thyristor Sij is commonly connected to a lighting signal line 75 that supplies a lighting signal φI for controlling the laser diode LD such that the laser diode LD is in a light emitting or non-light emitting state.

As will be described later, the reference potential Vsub is supplied via an electrode (not shown) provided on a rear surface of a GaAs substrate 80 constituting the light emitting component 10.

In the transfer thyristor T, the anode thereof is connected to the reference potential Vsub. The cathodes of the odd-numbered transfer thyristors T1, T3, are connected to a transfer signal line 72. The transfer signal line 72 is connected to a φ1 terminal via the current-limiting resistor R1.

The cathodes of the even-numbered transfer thyristors T2, T4, . . . are connected to a transfer signal line 73. The transfer signal line 73 is connected to a φ2 terminal via the current-limiting resistor R2.

The coupling diodes D are connected with each other in series. That is, the cathode of one coupling diode D is connected to the anode of the coupling diode D which is adjacent in the x direction. In the start diode SD, the anode is connected to the transfer signal line 73, and the cathode is connected to the anode of the coupling diode D1.

Then, the cathode of the start diode SD and the anode of the coupling diode D1 are connected to a gate Gt1 of the transfer thyristor T1. The cathode of the coupling diode D1 and the anode of the coupling diode D2 are connected to a gate Gt2 of the transfer thyristor T2. The same applies to the other coupling diode D.

The gate Gt of the transfer thyristor T is connected to a power line 71 via the power line resistor Rg. The power line 71 is connected to a Vgk terminal.

A gate Gti of the transfer thyristor Ti is connected to a gate Gsi of the setting thyristor Sij.

A configuration of the control unit 20 will be described.

The control unit 20 generates a signal such as a lighting signal φI and supplies the signal to the light emitting component 10. The light emitting component 10 operates in response to the supplied signal. The control unit 20 is composed of an electronic circuit. For example, the control unit 20 may be an integrated circuit (IC) configured to drive the light emitting component 10.

The control unit 20 comprises a transfer signal generation unit 21, a lighting signal generation unit 22, a power source potential generation unit 23, and a reference potential generation unit 24.

The transfer signal generation unit 21 generates transfer signals φ1 and φ2 so as to supply the transfer signal φ1 to the φ1 terminal of the light emitting component 10 and supply the transfer signal φ2 to the φ2 terminal of the light emitting component 10. The transfer signals φ1 and φ2 are signals which are “H (0 V)” or “L (−3.3 V)”. 0 V is a potential for turning off the transfer thyristor T, and −3.3 V is a potential for turning the transfer thyristor T from an OFF state to an ON state.

The lighting signal generation unit 22 generates the lighting signal φI and supplies the signal to a φ1 terminal of the light emitting component 10 via a current-limiting resistor RI. The lighting signal φI is a signal which is “H (0 V)” or “L (−3.3 V)”. 0 V is a potential for turning off the laser diode LD, and −3.3 V is a potential for turning the laser diode LD from the OFF state to the ON state. The current-limiting resistor RI may be provided in the light emitting component 10. Further, in a case where the current-limiting resistor RI is not necessary for an operation of the light emitting component 10, the current-limiting resistor RI does not have to be provided.

The power source potential generation unit 23 generates a power source potential Vgk to supply the potential to the Vgk terminal of the light emitting component 10. The reference potential generation unit 24 generates a reference potential Vsub to supply the potential to the Vsub terminal of the light emitting component 10. The power source potential Vgk is, for example, −3.3 V. As described above, the reference potential Vsub is a ground potential (GND) as an example.

In the light emitting component 10 shown in FIG. 1, four laser diodes LDij (j=1 to 4) are connected to one transfer thyristor Ti via the setting thyristors Sij, respectively.

The transfer thyristor Ti sets each LD/S group of the plurality of LD/S groups such that a lighting state or a non-lighting state propagates in sequence. Specifically, in a case where the transfer thyristor Ti is turned on, the setting thyristor Sij connected to the transfer thyristor Ti is set so as to be able to shift to the ON state. The transfer thyristor Ti is driven such that the ON state propagates. Therefore, the transfer thyristor Ti is referred to as a transfer thyristor T. In addition, in a case where the setting thyristor Sij is turned on, the laser diode LDij emits light. Therefore, since the laser diode LD is set to be capable of emitting light, a thyristor for the setting is referred to as a setting thyristor S.

Here, the plurality of LD/S groups are configured, the LD/S group is connected to each transfer thyristor T, and the laser diode LD belonging to the LD/S group emits light in parallel.

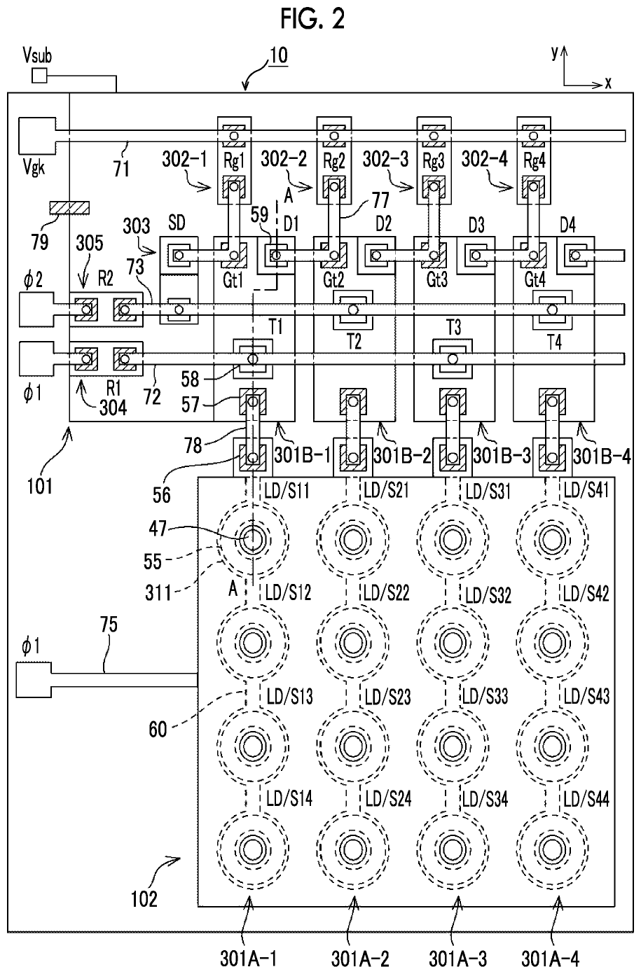

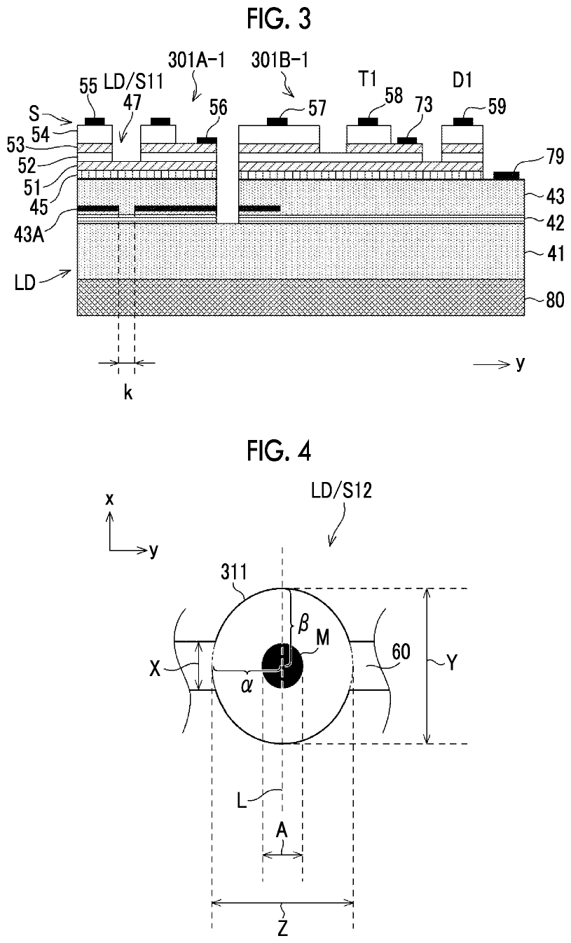

The laser diode LD may oscillate in, for example, a low-order single transverse mode (single mode). In the single mode, an intensity profile of the light (emitted light) emitted from a light emission point of the laser diode LD (light emission opening 47 in FIGS. 2 and 3 to be described later) is unimodal (characteristic of having one intensity peak). On the other hand, in the laser diode LD that oscillates in the multiple transverse mode (multi mode) including high order, the intensity profile tends to have distortion such as multiple peaks. Further, in the single mode, a spread angle of the light emitted from the light emission point (emitted light) is smaller than that in the multi mode. Therefore, in a case where the light output is the same, the single mode has a higher light density on an irradiated surface than the multi mode. The spread angle means a full width at a half maximum (FWHM) of the light emitted from the laser diode LD.

The smaller the area of the light emission point, the easier it is for the laser diode LD to oscillate in the single transverse mode (single mode). Therefore, the single mode laser diode LD has a small light output. In a case where the area of the light emission point is increased in an attempt to increase the light output, the mode shifts to the multi mode as described above. Therefore, in the first exemplary embodiment, the plurality of laser diodes LD are designated as the laser diode LD group, and the plurality of laser diodes LD included in the laser diode LD group are made to emit light in parallel to increase the light output.

FIG. 2 is a diagram showing an example of a planar layout of the light emitting component 10. On the page of FIG. 2, the left-right direction is the x direction and the up-down direction is the y direction. The x direction is the same as the x direction in FIG. 1. In FIG. 2, the light emitter 102 is a light emitting element array in which the plurality of LD/S groups each having the plurality of LD/S are arranged.

The light emitting component 10 is composed of a semiconductor material capable of emitting laser light. For example, the light emitting component 10 is composed of a GaAs-based compound semiconductor. Then, as shown in a cross-sectional view (refer to FIG. 3) to be described later, the light emitting component 10 is composed of a semiconductor layer laminate in which a plurality of GaAs-based compound semiconductor layers are laminated on a p-type GaAs substrate 80. Further, the light emitting component 10 is configured by separating the semiconductor layer laminate into a plurality of island-shaped pieces. An area left in the island shape is referred to as an island. Etching the semiconductor layer laminate in island shapes to separate the elements is called mesa etching. Here, the planar layout of the light emitting component 10 will be described with reference to islands 301, 302, 303, 304, and 305 shown in FIG. 2. In a case where the islands 301 and 302 are distinguished from each other, the islands 301 and 302 are represented as islands 301-i or 302-i (i≥1) as described above. The island 301 is separated into an island 301A in which the LD/S group is provided and an island 301B in which the transfer thyristor T and the coupling diode D are provided.

The island 301A-i is provided with the laser diode LDij and the setting thyristor Sij, and the island 301B-i is provided with the transfer thyristor Ti and the coupling diode Di (in this example, j=1 to 4). Then, in the islands 301A-i, posts 311, each of which is configured in an elliptical cylinder shape in accordance with an outer shape of the laser diode LD, are arranged. The post 311 is a part of the LD/S from which laser light is emitted. The post 311 is an example of a “light emitting unit”.

A part of each post 311 belonging to each LD/S group is continuous in the y direction at the facing part. Hereinafter, a part in which a part of each post 311 is continuous in the y direction is referred to as a “connection part 60”. That is, in each LD/S group, the plurality of LD/Ss are connected to each other by the connection part 60. In FIG. 2, each LD/S is described as LD/Sij to distinguish LD/S.

Further, the islands 301A-i are provided to be parallel to each other in the x direction. Here, the LD/S groups are one-dimensionally arranged in the x direction.

The island 302-i is provided with a power line resistor Rgi. The islands 302-i are provided so as to be parallel to each other in the x direction.

The island 303 is provided with the start diode SD. The island 304 is provided with the current-limiting resistor R1, and the island 305 is provided with the current-limiting resistor R2.

FIG. 3 is a cross-sectional view taken along the line A-A of FIG. 2. In FIG. 3, the left-right direction is the y direction.

FIG. 3 shows the LD/S11, the transfer thyristor T1, and the coupling diode D1 from the left.

First, the island 301A-1, which is provided with the LD/S11, will be described.

The LD/S11 is configured as a surface-emitting semiconductor layer laminate using a distributed Bragg reflector (DBR) waveguide. Then, as shown in FIG. 3, the LD/S11 has a structure in which the laser diode LD that generates the laser light and the setting thyristor S that controls the lighting and extinguishing of the laser diode LD are combined with a tunnel cementing layer 45 interposed therebetween on the GaAs substrate 80 which is a compound semiconductor substrate.

In the laser diode LD, an n-type nDBR layer 41, a resonator 42, and a p-type pDBR layer 43 are laminated on a GaAs substrate 80.

Next, in the LD/S11, the tunnel cementing layer 45 is laminated on the pDBR layer 43. The tunnel cementing layer 45 is configured by cementing an n⁺⁺ layer in which n-type impurities are added at a high concentration and a p⁺⁺ layer in which p-type impurities are added at a high concentration. The n⁺⁺ layer and the p⁺⁺ layer each have a high impurity concentration of, for example, 1×10²⁰/cm³.

In the LD/S11, the setting thyristor S is laminated on the tunnel cementing layer 45. The setting thyristor S is laminated in order of a cathode layer 51, a p-type A-gate layer 52, a n-type n-gate layer 53, and an anode layer 54. An electrode 55 is provided on the anode layer 54 of the setting thyristor S. The electrode 55 is provided in an elliptical shape to surround the light emission opening 47.

In the laser diode LD, laser light is generated through resonance of light having a specific wavelength between the upper pDBR layer 43 and the lower nDBR layer 41. Then, the laser light generated in the laser diode LD is emitted in the vertical direction from the light emission opening 47.

A part of the pDBR layer 43 is formed with a current constriction layer 43A generated by oxidation. The current constriction layer 43A is formed such that current flowing through the LD/S11 passes through the central part by constricting a current path of the current flowing through the LD/S11. Specifically, the central part of the current constriction layer 43A is formed as a current pass region K in which current easily flows, and a peripheral portion thereof is formed as a current block region in which current does not easily flow.

By providing such a current constriction layer 43A, power consumed for non-luminescence recombination is suppressed, and power consumption is reduced and a light emission efficiency is increased.

Here, the current constriction layer 43A is formed by oxidizing a part of the pDBR layer 43 as described above. It should be noted that oxidizing a part of the pDBR layer 43 to form the current constriction layer 43A may be referred to as oxidization constriction.

In the right end portion of the island 301A-1 in FIG. 3, an electrode 56 is provided on the n-gate layer 53 exposed except for the anode layer 54. The electrode 56 is connected to a wiring line 78 (refer to FIG. 2) via a through-hole provided in an interlayer insulating layer (not shown).

Although not shown in FIG. 3, the connection part 60 extends in the y direction from the left end portion of the LD/S11 and is connected to the adjacent LD/S12. For example, like the LD/S11, the connection part 60 has a structure in which the nDBR layer 41, the resonator 42, the pDBR layer 43, the tunnel cementing layer 45, the cathode layer 51, the p-gate layer 52, the n-gate layer 53, and the anode layer 54 are laminated on the GaAs substrate 80.

Next, the island 301B-1, which is provided with the transfer thyristor T1 and the coupling diode D1, will be described.

At the left end portion of the island 301B-1, an electrode 57 is provided on the anode layer 54. The electrode 57 is connected to the wiring line 78 (refer to FIG. 2) via a through-hole provided in an interlayer insulating layer (not shown). In such a manner, in a case where the transfer thyristor T is turned on and the gate Gt is 0 V, the gate Gs of the setting thyristor S is at 0 V via the wiring line 78. Consequently, the ON state of the transfer thyristor T is transmitted to the setting thyristor S.

In a similar manner to LD/S11, in the transfer thyristor T1 and the coupling diode D1, the nDBR layer 41, the resonator 42, the pDBR layer 43, the tunnel cementing layer 45, the cathode layer 51, the p-gate layer 52, the n-gate layer 53, and the anode layer 54 are laminated on the GaAs substrate 80.

The transfer thyristor T1 is provided with the electrode 58 on the anode layer 54 and functions as a gate for controlling the operation of the transfer thyristor T1. The electrode 58 is connected to the transfer signal line 72 (refer to FIG. 2).

The coupling diode D1 is provided with the electrode 59 on the anode layer 54. The electrode 59 is connected to the wiring line 77 (refer to FIG. 2).

The right end portion of the island 301B-1 exposes the pDBR layer 43. The exposed pDBR layer 43 and the GaAs substrate 80 are connected through a wiring line 79. In addition, in the part in which the transfer thyristor T1 and the coupling diode D1 are provided on the semiconductor layers (nDBR layer 41, resonator 42, and pDBR layer 43) constituting the laser diode LD, the nDBR layer 41, the resonator 42, and the pDBR layer 43 are short-circuited by the wiring line 79 such that the laser diode LD does not operate.

As described above, the light emitting component 10 uses the plurality of laser diodes LD as the laser diode LD group, and causes the plurality of laser diodes LD included in the laser diode LD group to emit light in parallel. In such a case, in a case where a wiring line for supplying a signal for controlling light emission or non-light emission of the laser diode LD is provided from the transfer unit 101 for each laser diode LD included in the laser diode LD group, a distance between the laser diodes LD has to be increased. Thus, an area of the light emitting component 10 increases.

Therefore, in the light emitting component 10, the setting thyristor S for setting the laser diode LD to be capable of emitting light is provided for each laser diode LD, and the setting thyristor S and the laser diode LD are laminated. Thereby, an increase in area of the light emitting component 10 is suppressed. Further, for each LD/S group, it is not necessary to provide a wiring line for supplying a signal for controlling light emission or non-light emission of the laser diode LD from the transfer unit 101 by connecting the semiconductor layer constituting the setting thyristor S by the connection part 60.

FIG. 4 is a diagram showing an example of a planar layout of the LD/S12. On the page of FIG. 4, the left-right direction is the y direction and the up-down direction is the x direction. The x direction and the y direction are the same as the x direction and the y direction in FIG. 2.

As shown in FIG. 4, the LD/S 12 comprises a post 311 and a connection part 60 extending from the post 311 in the y direction.

In the post 311 in plan view, a length α from the center, which is the intersection (origin) of the major axis and the minor axis of the ellipse, to the end portion in the y direction is shorter than a length β from the center to the end portion in the x direction which intersects the y direction. Here, the directions are orthogonal to each other. The y direction is an example of a “first direction”, and the x direction is an example of a “second direction”. Further, the x direction that intersects the y direction does not have to be orthogonal thereto, and may be tilted by several degrees from the vertical state.

Although not shown in FIG. 4, the connection part 60 connects the post 311 of the LD/S12 to the adjacent posts 311 of the LD/S11 and the LD/S13 (refer to FIG. 2). The length α is a length from the center of the post 311 to the end portion in the y direction. However, since the connection part 60 is connected to the post 311, the length α is a length between the center and the end portion of the post 311 on a virtual line or a shape of the post 311, from which the connection part 60 is removed, other than an end portion on an outer shape of combination of the connection part 60 and the post 311.

Here, in a case where the connection part 60 is provided in the LD/S, oxygen is supplied not only to the center side of the post 311 but also to the connection part 60 side in a case where the pDBR layer 43 (refer to FIG. 3) of the post 311 is oxidized. Thereby, there is a difference in the oxidized region between the part where the connection part 60 is provided and the part where the connection part 60 is not provided, and the shape of the unoxidized region of the post 311 (hereinafter referred to as “oxidized shape”) is distorted. For example, in a case where the plan view shape of the post 311 is a perfect circle, the oxidized shape is an elliptical shape having a large flattening ratio.

Therefore, in the first exemplary embodiment, as described above, the length α of the post 311 is made shorter than the length β in plan view. Thereby, in the first exemplary embodiment, the length of the post 311 in the x direction perpendicular to the connection part 60 increases. Therefore, even in a case where more regions than the part where the connection part 60 is provided are oxidized, the oxidized shape is not distorted. For example, in FIG. 4, the oxidized shape M has an elliptical shape having a smaller flattening ratio than that in the case where the plan view shape of the post 311 is a perfect circle. Therefore, according to the first exemplary embodiment, in a case where the connection part 60 is provided in the LD/S, a ratio of lengths of the unoxidized region of the post 311 in the y direction and the x direction can be set to be close to 1:1.

Further, the post 311 shown in FIG. 4 is line-symmetric with the straight line passing through the center as the axis of symmetry L in plan view. For example, the axis of symmetry L is along the x direction. The axis of symmetry L may be along the y direction instead of the x direction. Thereby, according to the first exemplary embodiment, the distortion of the shape of the unoxidized region of the post 311 is improved as compared with the case where the post 311 is not line-symmetric in plan view. Further, according to the first exemplary embodiment, the length between adjacent LD/Ss arranged as the light emitter 102 can be shortened as compared with the case where the axis of symmetry L is along a direction different from the x direction or the y direction.

Here, in FIG. 4, it is assumed that the length of the connection part 60 in the x direction is X, the length of the post 311 passing through the center in the x direction is Y, the length of the post 311 passing through the center in the y direction is Z, and the length of the unoxidized region in the current constriction layer 43A (refer to FIG. 3), that is, the current pass region K in the y direction. In such a case, the length of the post 311 passing through the center in the x direction is defined as Y=Z+X×N (0.1≤N≤0.9)×Z/(Z−A). Thereby, according to the first exemplary embodiment, the distortion of the shape of the unoxidized region of the post 311 is improved as compared with the case where N is less than 0.1 or greater than 0.9. In a case where N is less than 0.1, the plan view shape of the post 311 is a substantially perfect circle, and the oxidized shape is an elliptical shape having a large flattening ratio. In a case where N is greater than 0.9, the length of the current pass region K in the x direction is remarkably longer than the length in the y direction, and the oxidized shape is an elliptical shape having a large flattening ratio.

### Second Exemplary Embodiment

Next, a second exemplary embodiment will be described while omitting or simplifying an overlapping part with the other exemplary embodiments.

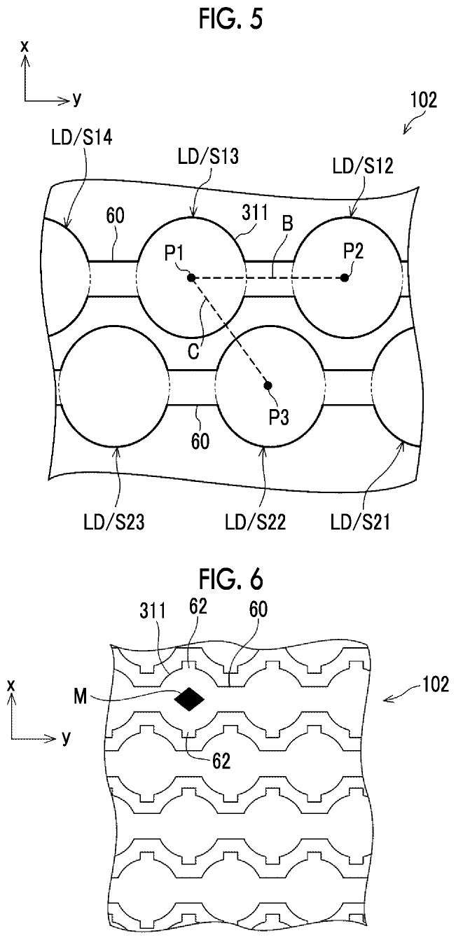

FIG. 5 is a first explanatory view showing a planar layout of a part of the light emitter 102. On the page of FIG. 5, the left-right direction is the y direction and the up-down direction is the x direction. The x direction and the y direction are the same as the x direction and the y direction in FIG. 4.

In the second exemplary embodiment, the plurality of LD/Ss constituting the light emitter 102 are arranged in an orthorhombic grid pattern. In this point of view, the second exemplary embodiment is different from the first exemplary embodiment in which the plurality of LD/S constituting the light emitter 102 are arranged in a square grid pattern. In such a case, in the second exemplary embodiment, the length from the center of one LD/S in one LD/S group of the plurality of LD/S groups to the center of the LD/S adjacent to the one LD/S is longer than the length from the center of one LD/S to the center of the LD/S adjacent to one LD/S in another LD/S group adjacent to one LD/S group. For example, in FIG. 5, a description will be given in a case where one LD/S is “LD/S13”, an LD/S adjacent to the one LD/S is “LD/S12”, and an LD/S adjacent to the one LD/S in another LD/S group adjacent to one LD/S group is “LD/S22”. In such a case, as shown in FIG. 5, a length B from a center P1 of the LD/S13 to a center P2 of the LD/S12 is longer than a length C from the center P1 of the LD/S13 to a center P3 of the LD/S22.

With such a configuration, according to the second exemplary embodiment, the light emitter 102 as the light emitting element array can be miniaturized as compared with the case where the lengths between the centers of all the adjacent LD/S are equal.

### Third Exemplary Embodiment

Next, a third exemplary embodiment will be described while omitting or simplifying the overlapping part with the other exemplary embodiments.

A plan view shape of the post 311 in the third exemplary embodiment is not configured as an elliptical shape unlike plan view shapes of the post 311 in the other exemplary embodiments.

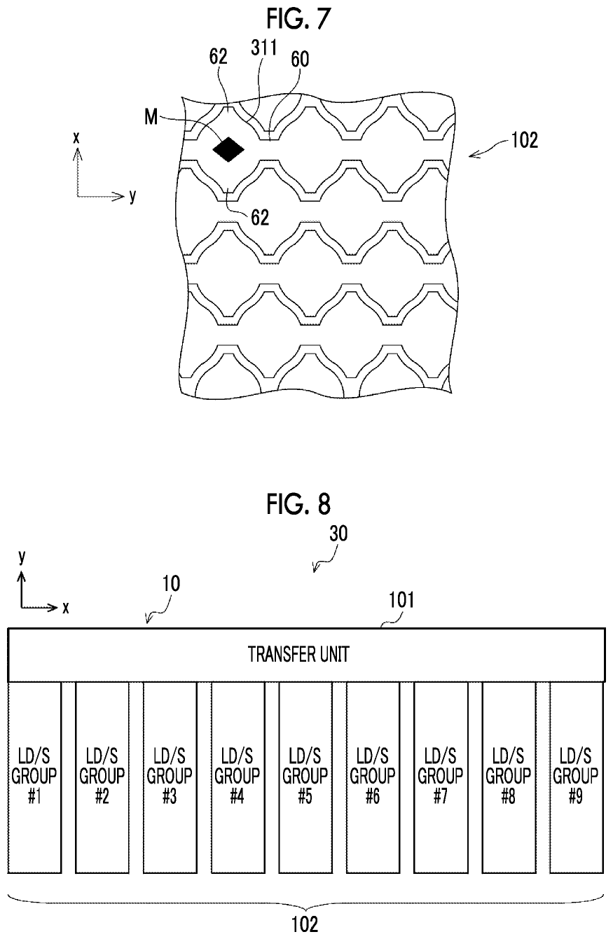

FIG. 6 is a second explanatory view showing a partial planar layout of the light emitter 102, and FIG. 7 is a third explanatory view showing a partial planar layout of the light emitter 102. On the pages of FIGS. 6 and 7, the left-right direction is the y direction and the up-down direction is the x direction. The x direction and the y direction are the same as the x direction and the y direction in FIG. 4.

As shown in FIG. 6, at both end portions of each post 311 in the x direction, extension sections 62 in which the semiconductor layer of the post 311 extends in the x direction are provided. The shape of the extension section 62 in FIG. 6 is rectangular. For example, in FIG. 6, since the post 311 is provided with the extension section 62, the oxidized shape M has a rhombic shape in which the ratio of lengths in the y direction and the x direction is set to be close to 1:1.

As shown in FIG. 7, the extension sections 62 are provided at both end portions of each post 311 in the x direction. The shape of each extension section 62 in FIG. 7 is a substantially trapezoidal shape. For example, in FIG. 7, since the post 311 is provided with the extension section 62, the oxidized shape M has a rhombic shape in which the ratio of lengths in the y direction and the x direction is set to be close to 1:1.

As described above, the configuration, in which the length from the center of the post 311 to the end portion in the y direction is shorter than the length from the center to the end portion in the x direction, is not limited to a configuration in which the plan view shape of the post 311 is made elliptical, but both end portions of each post 311 in the x direction may be extended in the x direction.

### Fourth Exemplary Embodiment

Next, a fourth exemplary embodiment will be described while omitting or simplifying the overlapping part with the other exemplary embodiments.

The optical device 30 in the fourth exemplary embodiment employs the light emitting component 10 described in the first to third exemplary embodiments.

FIG. 8 is a schematic diagram showing a configuration of the optical device 30. Then, the left-right direction is the x direction and the up-down direction is the y direction.

The optical device 30 comprises a light emitting component 10 and an optical element (not shown). The light emitting component 10 comprises nine LD/S groups (LD/S groups #1 to #9) and a transfer unit 101 one-dimensionally arranged in the x direction on the light emitter 102. The detailed description of the transfer unit 101 will not be repeated. Then, the optical device 30 comprises an optical element that sets a direction or a spread angle of the light emitted from each LD/S group in the plurality of LD/S groups included in the light emitting component 10 to a predetermined direction or a predetermined spread angle. Hereinafter, for example, a description will be given in a case where the optical element is a convex lens (hereinafter referred to as a lens LZ) and the emission direction of light is deflected in the predetermined direction. For example, the LD/S group #1 is disposed with the center of the lens LZ shifted in the x direction with respect to the center of the light emission opening 47 (refer to FIG. 3) of the laser diode LD so as to deflect the light emitted by the laser diode LD in the x direction.

In a case where the lens LZ is a small lens such as a micro lens, the deflection angle may be small. In such a case, another lens may be provided on the front surface of the optical device 30 provided with the lens LZ so as to increase the deflection angle. Further, the lens LZ has been described as a convex lens but may be a concave lens or an aspherical lens.

Further, in the above description, the emission direction of light is deflected, but the spread angle may be changed. For example, the convex lens may be employed to focus the light on the irradiated surface, or the light may be spread so as to be irradiated in a predetermined range on the irradiated surface.

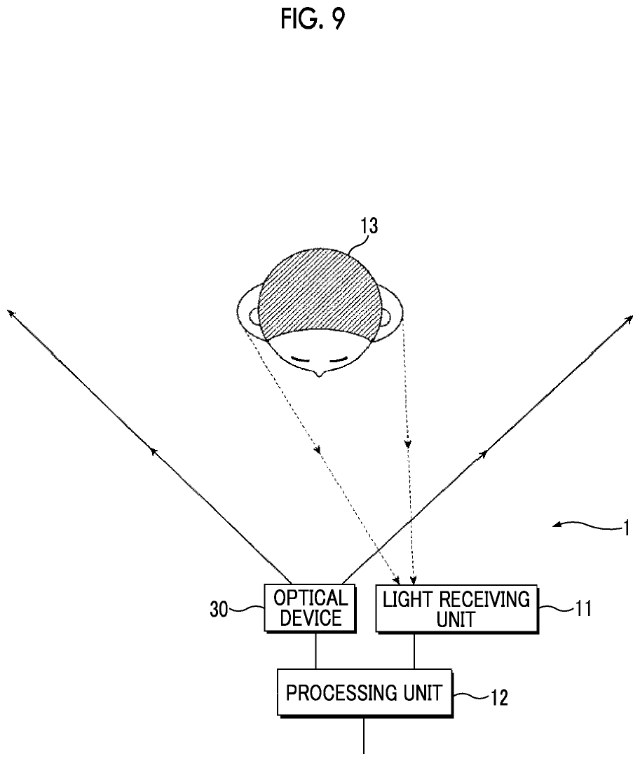

FIG. 9 is a schematic diagram showing a configuration of an optical measurement apparatus 1 provided with the optical device 30. The optical measurement apparatus 1 comprises an optical device 30, a light receiving unit 11 that receives reflected light from a measurement target object (target object) 13 irradiated with light from the optical device 30, and a processing unit 12 that processes information about the light received by the light receiving unit 11 so as to measure the distance from the optical device 30 to the measurement target object 13 or the shape of the measurement target object 13. Then, the measurement target object 13 is set to be close to the optical measurement apparatus 1. The measurement target object 13 is, for example, a human being. Then, FIG. 9 is a diagram viewed from above.

The light receiving unit 11 is a device that receives the light reflected by the measurement target object 13. The light receiving unit 11 may be a photodiode. The photodiode is, for example, a single photon avalanche diode (SPAD) that can accurately measure the light receiving time.

The processing unit 12 is configured as a computer including an input output unit for inputting and outputting data. Then, the processing unit 12 processes the information about the light so as to calculate the distance to the measurement target object 13 and the two-dimensional or three-dimensional shape of the measurement target object 13.

The processing unit 12 of the optical measurement apparatus 1 controls the light emitting component 10 of the optical device 30 so as to emit the light from the light emitting component 10. That is, the light emitting component 10 of the optical device 30 emits the light in a pulse shape. Then, the processing unit 12 calculates an optical path length until light is emitted from the optical device 30, then reflected by the measurement target object 13, and reaches the light receiving unit 11, on the basis of the time difference between the time at which the light emitting component 10 emits light and the time at which the light receiving unit 11 receives the reflected light from the measurement target object 13. Therefore, the processing unit 12 measures a distance from the optical device 30 and the light receiving unit 11 or a distance from a point serving as a reference (hereinafter referred to as the reference point) to the measurement target object 13. In addition, the reference point is a point provided at a predetermined position from the optical device 30 and the light receiving unit 11.

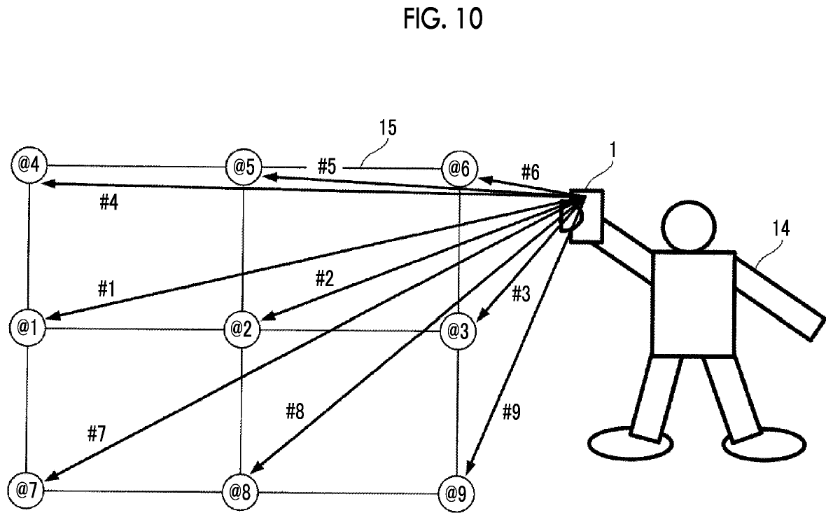

FIG. 10 is a diagram showing a state where light is emitted from the optical measurement apparatus 1. Here, it is assumed that the person 14 holds the optical measurement apparatus 1 in his or her right hand and measures presence or absence of the target object in front of him or her.

For example, light from the LD/S group #1 of the light emitting component 10 in the optical device 30 travels toward a region @1 of the irradiated surface 15 virtually set. Further, the light from the LD/S group #2 travels toward a region @2. In such a manner, light is emitted from the LD/S groups #1 to #9 toward different regions @1 to @9. Then, the light receiving unit 11 receives the reflected light. Then, the processing unit 12 measures the time that elapses until the light is emitted and then the light receiving unit 11 receives the reflected light. Then, it is possible to detect which direction the measurement target object 13 is located in. That is, the optical measurement apparatus 1 is a proximity sensor. Further, the two-dimensional or three-dimensional shape of the measurement target object 13 is measured from the distance to the measurement target object 13.

The method is a surveying method based on a light arrival time, and is called a time-of-flight (TOF) method. In the method, for example, light having a shape of a plurality of pulses is emitted in order to improve a measurement accuracy. Further, the number of pulses may be increased to improve the measurement accuracy, in a specific direction, for example, in FIG. 10, for the region @2 on the front side. That is, a period for irradiating the region @2 with light may be longer than other periods, and the number of pulses may be increased.

The optical device 30 sequentially emits light in the predetermined direction. Therefore, the optical device 30 has a resolution lower than that in a case where light is emitted simultaneously in multiple directions, but consumes less power. Further, in a case where light is emitted simultaneously in multiple directions, it is necessary to identify the direction in which the reflected light comes by using the light receiving elements in which the light receiving elements are arranged two-dimensionally. In contrast, in the optical measurement apparatus 1 that emits light by sequentially changing the direction, it is not necessary to use a light receiving element in which light receiving elements are arranged in two dimensions, and it suffice to use a light receiving element capable of measuring a change in the intensity of the received light at high speed. Therefore, the configuration of the optical measurement apparatus 1 is simplified.

The light emitting component 10 in the optical device 30 shown in FIG. 8 comprises nine LD/S groups #1 to #9. Then, as shown in FIG. 10, nine regions @1 to @9 of 3×3 are irradiated. Therefore, in a case where increasing the number of regions, the number of LD/S groups to be arranged may be changed. In a case of irradiating 25 regions @1 to @25 of 5×5, 25 LD/S groups may be provided. In addition, 20 areas of 5×4 and 4×5 may be used. Further, the LD/S group is arranged in one dimension, but may be arranged in two dimensions. Further, the irradiated regions do not have to be arranged in a grid pattern. The optical element such as the lens LZ may be set to set the emission direction of light from the laser diode LD of the light emitting component 10 in the optical device 30 so as to irradiate a location to be measured.

As described above, the optical device 30 in the fourth exemplary embodiment sequentially drives the LD/S groups in the light emitting component 10 along the arrangement so as to irradiate the light in a planar manner. That is, light is emitted into a two-dimensional space through a one-dimensional operation.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A light emitting element comprising:
a light emitting unit that has a plurality of semiconductor layers laminated, the light emitting unit having a length from a center of the light emitting unit to an end portion in a first direction shorter than a length from the center to an end portion in a second direction intersecting the first direction, in plan view; and
a connection part that extends from the light emitting unit in the first direction and connects the light emitting unit to another semiconductor layer.

2. The light emitting element according to claim 1,
wherein the light emitting unit is line-symmetric with a straight line passing through the center as an axis of symmetry in plan view.

3. The light emitting element according to claim 2,
wherein the axis of symmetry is along the first direction or the second direction.

4. The light emitting element according to claim 1, wherein
assuming that a length of the connection part in the second direction is X, a length of the light emitting unit passing through the center in the second direction is Y, a length of the light emitting unit passing through the center in the first direction is Z, and a length of an unoxidized region in the first direction in a current constriction layer among the plurality of semiconductor layers is A,
the length of the light emitting unit passing through the center in the second direction is defined by Y=Z+X×N (0.1≤N≤0.9)×Z/(Z−A).

5. The light emitting element according to claim 2, wherein
assuming that a length of the connection part in the second direction is X, a length of the light emitting unit passing through the center in the second direction is Y, a length of the light emitting unit passing through the center in the first direction is Z, and a length of an unoxidized region in the first direction in a current constriction layer among the plurality of semiconductor layers is A,
the length of the light emitting unit passing through the center in the second direction is defined by Y=Z+X×N (0.1≤N≤0.9)×Z/(Z−A).

6. The light emitting element according to claim 3, wherein
assuming that a length of the connection part in the second direction is X, a length of the light emitting unit passing through the center in the second direction is Y, a length of the light emitting unit passing through the center in the first direction is Z, and a length of an unoxidized region in the first direction in a current constriction layer among the plurality of semiconductor layers is A,
the length of the light emitting unit passing through the center in the second direction is defined by Y=Z+X×N (0.1≤N≤0.9)×Z/(Z−A).

7. A light emitting element array comprising a plurality of light emitting elements according to claim 1,
wherein a plurality of light emitting element groups each having the plurality of the light emitting elements are arranged, and
in the light emitting element groups, the plurality of the light emitting elements are connected to each other through the connection part.

8. A light emitting element array comprising a plurality of light emitting elements according to claim 2,
wherein a plurality of light emitting element groups each having the plurality of the light emitting elements are arranged, and
in the light emitting element groups, the plurality of the light emitting elements are connected to each other through the connection part.

9. A light emitting element array comprising a plurality of light emitting elements according to claim 3,
wherein a plurality of light emitting element groups each having the plurality of the light emitting elements are arranged, and
in the light emitting element groups, the plurality of the light emitting elements are connected to each other through the connection part.

10. A light emitting element array comprising a plurality of light emitting elements according to claim 4,
wherein a plurality of light emitting element groups each having the plurality of the light emitting elements are arranged, and
in the light emitting element groups, the plurality of the light emitting elements are connected to each other through the connection part.

11. A light emitting element array comprising a plurality of light emitting elements according to claim 5,
wherein a plurality of light emitting element groups each having the plurality of the light emitting elements are arranged, and
in the light emitting element groups, the plurality of the light emitting elements are connected to each other through the connection part.

12. A light emitting element array comprising a plurality of light emitting elements according to claim 6,
wherein a plurality of light emitting element groups each having the plurality of the light emitting elements are arranged, and
in the light emitting element groups, the plurality of the light emitting elements are connected to each other through the connection part.

13. The light emitting element array according to claim 7,
wherein a length from the center of one light emitting element in one light emitting element group of the plurality of light emitting element groups to the center of the light emitting element adjacent to the one light emitting element is longer than a length from the center of the one light emitting element to the center of the light emitting element adjacent to the one light emitting element in another light emitting element group adjacent to the one light emitting element group.

14. The light emitting element array according to claim 8,
wherein a length from the center of one light emitting element in one light emitting element group of the plurality of light emitting element groups to the center of the light emitting element adjacent to the one light emitting element is longer than a length from the center of the one light emitting element to the center of the light emitting element adjacent to the one light emitting element in another light emitting element group adjacent to the one light emitting element group.

15. The light emitting element array according to claim 9,
wherein a length from the center of one light emitting element in one light emitting element group of the plurality of light emitting element groups to the center of the light emitting element adjacent to the one light emitting element is longer than a length from the center of the one light emitting element to the center of the light emitting element adjacent to the one light emitting element in another light emitting element group adjacent to the one light emitting element group.

16. The light emitting element array according to claim 10,
wherein a length from the center of one light emitting element in one light emitting element group of the plurality of light emitting element groups to the center of the light emitting element adjacent to the one light emitting element is longer than a length from the center of the one light emitting element to the center of the light emitting element adjacent to the one light emitting element in another light emitting element group adjacent to the one light emitting element group.

17. The light emitting element array according to claim 11,
wherein a length from the center of one light emitting element in one light emitting element group of the plurality of light emitting element groups to the center of the light emitting element adjacent to the one light emitting element is longer than a length from the center of the one light emitting element to the center of the light emitting element adjacent to the one light emitting element in another light emitting element group adjacent to the one light emitting element group.

18. A light emitting component comprising:
the light emitting element array according to claim 7; and
a setting unit that sets each light emitting element group of the plurality of light emitting element groups included in the light emitting element array such that a lighting state or a non-lighting state propagates in sequence.

19. An optical device comprising:
the light emitting component according to claim 18; and
an optical element that sets a direction or a spread angle of light emitted from each light emitting element group in the plurality of light emitting element groups included in the light emitting component to a predetermined direction or a predetermined spread angle.

20. An optical measurement apparatus comprising:
the optical device according to claim 19;
a light receiving unit that receives reflected light from a target object irradiated with light from the optical device; and
a processing unit that processes information about light received by the light receiving unit to measure a distance from the optical device to the target object or a shape of the target object.
